(19) United States
(12) Patent Application Publication
(10) Pub. No.: US 2023/0120110 A1
(43) Pub. Date: Apr. 20, 2023

(54) CONVERTIBLE INTERCONNECT BARRIER

(71) Applicant: International Business Machines Corporation, Armonk, NY (US)

(72) Inventors: Koichi Motoyama, Clifton Park, NY (US); CHANRO PARK, CLIFTON PARK, NY (US); Kenneth Chun Kuen Cheng, Shatin (HK); Chih-Chao Yang, Glenmont, NY (US)

(21) Appl. No.: 17/451,218

(22) Filed: Oct. 18, 2021

(51) Int. Cl. H01L 21/768; H01L 23/522; H01L 23/532

(52) U.S. Cl. CPC H01L 21/76846; H01L 21/76804; H01L 21/76877; H01L 23/5226; H01L 23/53238

(57) ABSTRACT

A method of making a semiconductor component includes forming a lower level including an interconnect structure. The method includes forming an upper level including a first dielectric layer, a second dielectric layer, and a barrier layer arranged between the first and second dielectric layers. The method includes forming a cavity in the upper level such that a portion of the interconnect structure and a portion of the barrier layer are exposed. The method includes forming a barrier material on all surfaces exposed by the formation of the cavity. The method includes removing the barrier material from all substantially horizontal surfaces exposed by the formation of the cavity. The method includes filling the cavity with an interconnect material such that the interconnect material is in direct contact with the interconnect structure and the barrier layer.

### BACKGROUND

The present disclosure relates to the electrical, electronic, and computer fields. In particular, the present disclosure relates to the interconnects of semiconductor devices and methods of making the interconnects of semiconductor devices.

In integrated circuits, interconnects are structures that connect two or more circuit elements together electrically. In addition to providing the electrical connection to the front end devices (such as transistors), interconnects also go all the way back to the power delivery networks. Thus, interconnects, and their surrounding support components, are considered back-end-of-line (BEOL) components. Lines provide electrical connection within a single layer, and vias provide electrical connection between layers in a physical electronic circuit.

### SUMMARY

Embodiments of the present disclosure include a method of making a semiconductor component. The method includes forming a lower level including an interconnect structure. The method further includes forming an upper level including a first dielectric layer, a second dielectric layer, and a barrier layer arranged between the first and second dielectric layers. The method further includes forming a cavity in the upper level such that a portion of the interconnect structure and a portion of the barrier layer are exposed. The method further includes forming a barrier material on all surfaces exposed by the formation of the cavity. The method further includes removing the barrier material from all substantially horizontal surfaces exposed by the formation of the cavity. The method further includes filling the cavity with an interconnect material such that the interconnect material is in direct contact with the interconnect structure and the barrier layer.

Additional embodiments of the present disclosure include a semiconductor component. The semiconductor component includes a lower level line separated from surrounding dielectric material by a sidewall made of a first liner material. The semiconductor component further includes a via arranged in direct contact with the lower level line and separated from surrounding dielectric material by a sidewall made of a second liner material. The semiconductor component further includes an upper level line arranged in direct contact with the via and separated from surrounding dielectric material by a sidewall made of the second liner material and by a bottom wall made of a third liner material.

Additional embodiments of the present disclosure include a semiconductor component. The semiconductor component includes a continuous interconnect structure made of a single piece of interconnect material extending from a bottom surface of the interconnect structure to a top surface of the interconnect structure. The interconnect structure includes a lower level line, an upper level line, and a via extending from the lower level line to the upper level line.

The above summary is not intended to describe each illustrated embodiment or every implementation of the present disclosure.

### BRIEF DESCRIPTION OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

FIG. 1 is a schematic diagram illustrating an example semiconductor component including a lower level line, an upper level via, and an upper level line, in accordance with embodiments of the present disclosure.

FIG. 2A is a schematic diagram illustrating an example semiconductor component following the performance of a portion of an example method, in accordance with embodiments of the present disclosure.

FIG. 2B is a schematic diagram illustrating the example semiconductor component of FIG. 2A following the performance of a further portion of the example method, in accordance with embodiments of the present disclosure.

FIG. 3 illustrates a flowchart of an example method for forming a semiconductor component, in accordance with embodiments of the present disclosure.

FIG. 4A illustrates an example of a component following the performance of a portion of the example method of FIG. 3, in accordance with embodiments of the present disclosure.

FIG. 4B illustrates an example of a component following the performance of a portion of the example method of FIG. 3, in accordance with embodiments of the present disclosure.

FIG. 4C illustrates an example of a component following the performance of a portion of the example method of FIG. 3, in accordance with embodiments of the present disclosure.

FIG. 4D illustrates an example of a component following the performance of a portion of the example method of FIG. 3, in accordance with embodiments of the present disclosure.

FIG. 4E illustrates an example of a component following the performance of a portion of the example method of FIG. 3, in accordance with embodiments of the present disclosure.

FIG. 4F illustrates an example of a component following the performance of a portion of the example method of FIG. 3, in accordance with embodiments of the present disclosure.

FIG. 4G illustrates an example of a component following the performance of a portion of the example method of FIG. 3, in accordance with embodiments of the present disclosure.

FIG. 4H illustrates an example of a component following the performance of a portion of the example method of FIG. 3, in accordance with embodiments of the present disclosure.

FIG. 4I illustrates an example of a component following the performance of a portion of the example method of FIG. 3, in accordance with embodiments of the present disclosure.

FIG. 4J illustrates an example of a component following the performance of a portion of the example method of FIG. 3, in accordance with embodiments of the present disclosure.

FIG. 4K illustrates an example of a component following the performance of a portion of the example method of FIG. 3, in accordance with embodiments of the present disclosure.

FIG. 4L illustrates an example of a component following the performance of a portion of the example method of FIG. 3, in accordance with embodiments of the present disclosure.

### DETAILED DESCRIPTION

Aspects of the present disclosure relate generally to the electrical, electronic, and computer fields. In particular, the present disclosure relates to semiconductor devices. While the present disclosure is not necessarily limited to such applications, various aspects of the disclosure may be appreciated through a discussion of various examples using this context.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

Turning now to an overview of technologies that are more specifically relevant to aspects of the present disclosure, in integrated circuits, interconnects are structures that connect two or more circuit elements (such as transistors or power rails) together electrically. In addition to providing the electrical connection to the front end devices (such as transistors), interconnects also go all the way back to the power delivery networks. Thus, interconnects, and their surrounding support components, are considered back-end-of-line (BEOL) components. Lines provide electrical connection within a single layer, and vias provide electrical connection between layers in a physical electronic circuit.

In current interconnect technologies, interconnects are typically made of copper due to its low resistivity. However, as interconnect technology is scaled to smaller sizes, copper begins to suffer from problematic diffusion. Accordingly, liner materials, also referred to as barrier materials, are typically used to line a trench or cavity formed in the dielectric material that is filled with the interconnect material. Thus, the liner or barrier material is arranged between the copper interconnect and the surrounding dielectric material. However, copper does not adhere well to all liner materials that are commonly used to form barriers between the interconnect structures and the surrounding dielectric material.

Selecting a material to use as a liner/barrier material depends on the desired resistivity and adhesion that the material will provide to the interconnect structure. Tantalum disulfide (TaS2) is one illustrative material that can be well suited for use as a liner/barrier material because it provides good barrier performance against copper diffusion, even at very thin thicknesses (for example, thicknesses of approximately 1.5 nanometers). Additionally, as a liner, TaS2 has good adhesion to copper and to dielectric materials. Accordingly, TaS2 can be used both to prevent problematic copper diffusion and to promote adhesion of copper within the dielectric material. In particular, TaS2 is a two-dimensional (2D) metallic transition metal dichalcogenide (MTMDC) material that exhibits superconductivity, charge-density wave behavior, and metal-insulator transitions.

Because TaS2 can provide these benefits even at very thin thicknesses, the volume of copper in lined trenches or cavities can be maximized, which reduces line resistance. However, via resistance is still a concern when using TaS2 as a liner/barrier material because of its high film resistivity at the bottom of a via.

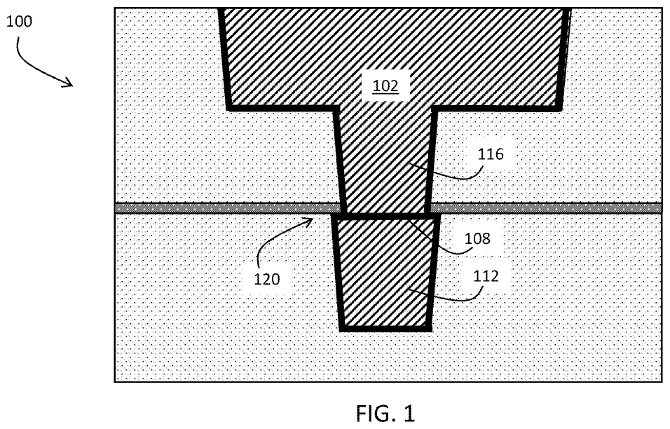

As an illustrative example, FIG. 1 depicts a semiconductor component 100 including an interconnect structure 102. As shown in FIG. 1, where TaS2 is used as a liner/barrier material in a via, a thin layer of TaS2 108 is arranged at the via bottom, between areas of copper that form a lower level interconnect structure 112 and the via 116 in the interconnect structure 102. The resulting interface 120 of copper 112, TaS2 108, and copper 116 produces very high via resistance. Accordingly, it is desirable to use a thin layer of TaS2 as a liner/barrier material for the copper interconnect structure 102, but to remove the layer of TaS2 at the interface 120 at the via bottom between the areas of copper 112, 116.

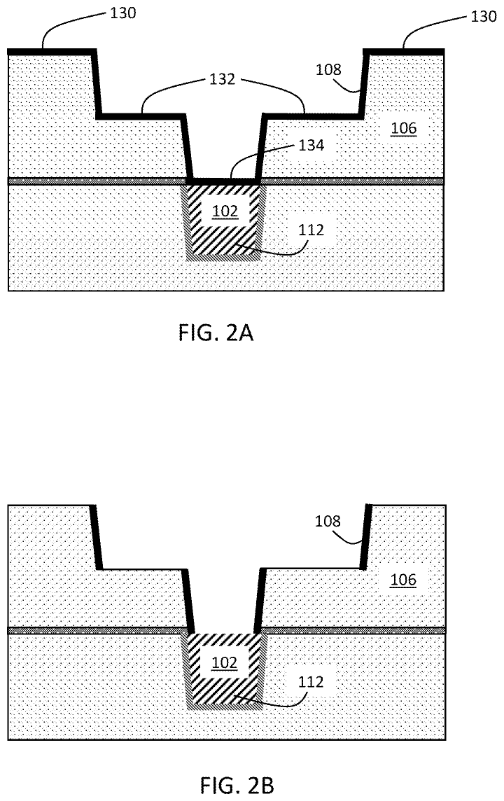

One way to remove the layer of TaS2 from the interface 120 (shown in FIG. 1) is to perform a TaS2 etch back, as discussed with reference to FIGS. 2A and 2B. As shown in FIG. 2A, the layer of TaS2 108 has been applied as a liner/barrier to the interconnect structure 102, including on top of the area of copper of the lower level interconnect structure 112. Accordingly, the layer of TaS2 108 forms horizontal portions 130 at the top of the dielectric material 106, horizontal portions 132 at the bottom of the line trench that will be filled with copper to form an upper line of the interconnect structure 102, and a horizontal portion 134 at the bottom of the via trench that will be filled with copper to form the via of the interconnect structure 102.

As shown in FIG. 2B, after the layer of TaS2 108 has been applied, an etch back process is performed to remove the horizontal portion 134 (shown in FIG. 2A) at the bottom of the via trench, which will prevent the formation of an interface such as the interface 120 shown in FIG. 1. However, performing this directional etch also removes the horizontal portions 130 (shown in FIG. 2A) at the top of the dielectric material 106 and the horizontal portions 132 (shown in FIG. 2A) at the bottom of the upper line trench. The removal of the horizontal portions 132 in particular is undesirable because it will enable copper diffusion from the subsequently produced line into the surrounding dielectric material 106. Such copper diffusion can lead to shorting and negatively impacts performance of the semiconductor device.

Embodiments of the present disclosure may overcome these and other drawbacks of existing solutions by enabling the removal of a liner/barrier material from the bottom of a via trench while maintaining the presence of a liner/barrier material in the bottom of a line trench of an interconnect structure. As discussed in further detail below, such embodiments include depositing the liner/barrier material on top of a barrier layer that forms the bottom of the line trench. Such embodiments further include selectively removing the liner/barrier material from the horizontal surfaces that form the bottoms of the via trench and the line trench. Accordingly, in such embodiments, the liner/barrier material is removed from the top of the barrier layer, and the barrier layer remains and continues to form the bottom of the trench line. Further, in such embodiments, the remaining liner/barrier material forms side walls that abut, and are in direct contact with, the barrier layer that forms the bottom of the trench line. Thus, such embodiments enable the removal of the liner/barrier material from the bottom of the via trench while maintaining the presence of the liner/barrier material in the bottom of the line trench. Accordingly, such embodiments prevent copper diffusion into surrounding dielectric material and prevent the formation of a high via resistance interface.

In general, the various processes used to form lines and vias for a semiconductor chip or micro-chip that will be packaged into an IC fall into three general categories, namely, deposition, removal/etching, and patterning/lithography.

Deposition is any process that grows, coats, or otherwise transfers a material onto the substrate. Available technologies include physical vapor deposition (PVD), chemical vapor deposition (CVD), electrochemical deposition (ECD), molecular beam epitaxy (MBE) and more recently, atomic layer deposition (ALD) among others. Another deposition technology is plasma enhanced chemical vapor deposition (PECVD), which is a process which uses the energy within the plasma to induce reactions at the substrate surface that would otherwise require higher temperatures associated with conventional CVD. Energetic ion bombardment during PECVD deposition can also improve the film's electrical and mechanical properties.

Removal/etching is any process that removes material from the substrate. Examples include etch processes (either wet or dry), chemical-mechanical planarization (CMP), and the like. One example of a removal process is ion beam etching (IBE). In general, IBE (or milling) refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on substrates. With RIE the plasma is generated under low pressure (vacuum) by an electromagnetic field. High-energy ions from the RIE plasma attack the substrate surface and react with it to remove material.

Patterning/lithography is the formation of three-dimensional relief images or patterns on the semiconductor substrate for subsequent transfer of the pattern to a layer arranged beneath the pattern. In semiconductor lithography, the patterns are formed by a light sensitive polymer called a photoresist.

To build the complex structures that make up a transistor and the many wires that connect the millions of transistors of a circuit, lithography and etch pattern transfer steps are repeated multiple times. Each pattern being printed on the substrate is aligned to previously formed patterns, and gradually the conductive and insulative regions are built up to form the final device.

These processes can be used in different combinations and orders within the context of two main integration schemes for forming lines and vias. A subtractive scheme refers to processes of forming line and via structures by depositing metal, and then etching the metal to form lines and vias. Alternatively, a damascene scheme refers to the processes of forming line and via structures by depositing an oxide layer, forming a trench into the oxide layer, and then depositing metal into the trench. In particular, in a typical dual damascene process (also referred to as a dual damascene flow), a structure undergoes a diffusion barrier etch step, then a via dielectric is deposited. A subsequent etch step then forms a gap in which metal is deposited to form the lines and vias simultaneously. Subtractive and damascene schemes can both be used in the formation of complex interconnect structures.

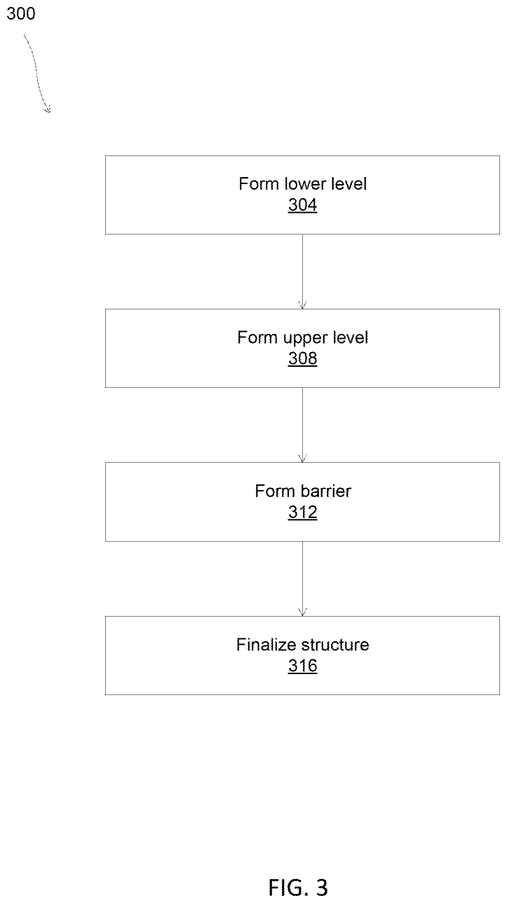

FIG. 3 depicts a flowchart of an example method 300 for forming a semiconductor component, according to embodiments of the present disclosure. The method 300 begins with operation 304, wherein a lower level of the interconnect structure is formed. In accordance with at least one embodiment of the present disclosure, operation 304 further includes a number of sub-operations.

More specifically, the performance of operation 304 includes forming a first dielectric layer on top of a substrate, forming a lower level line trench in the first dielectric layer, and coating the resulting structure with a very thin layer of barrier material. Accordingly, the resulting barrier layer made of the barrier material covers the first dielectric layer, including the surfaces of the trench. In accordance with at least one embodiment, the first dielectric layer may be made of, for example, a low-k dielectric material. In accordance with at least one embodiment, the barrier material may be, for example, tantalum. In accordance with at least one embodiment, the barrier layer may have a thickness of, for example, approximately 1-3 nanometers.

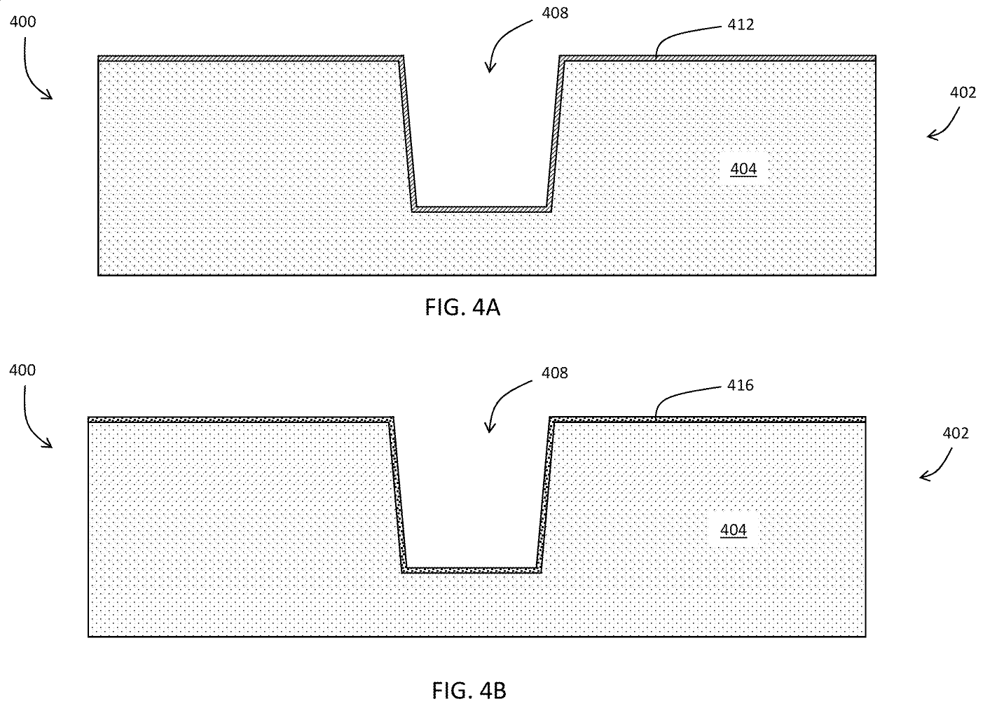

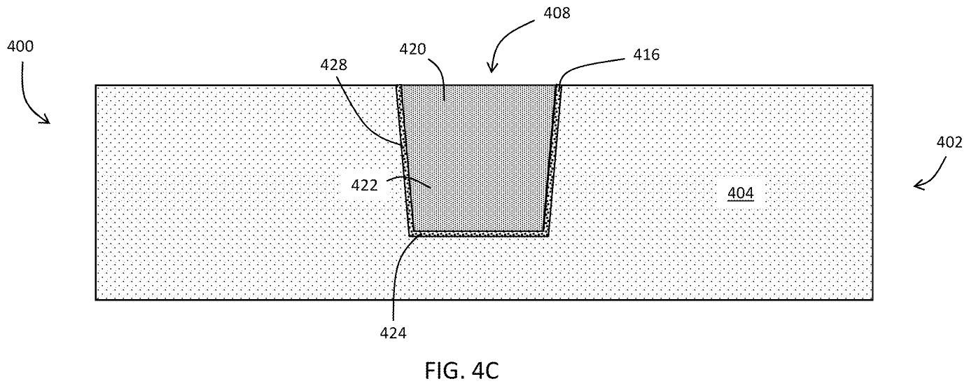

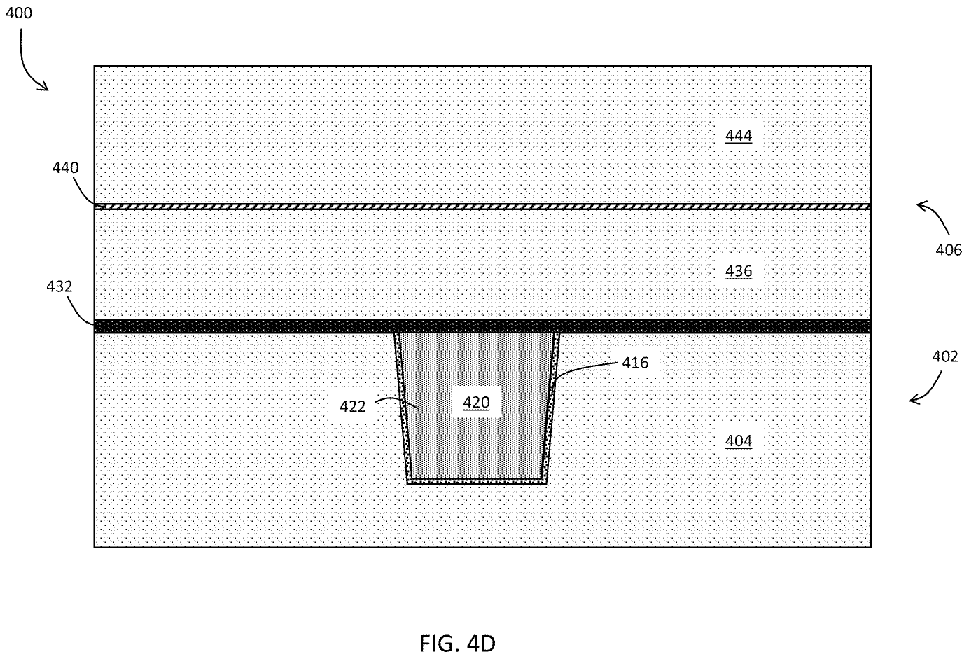

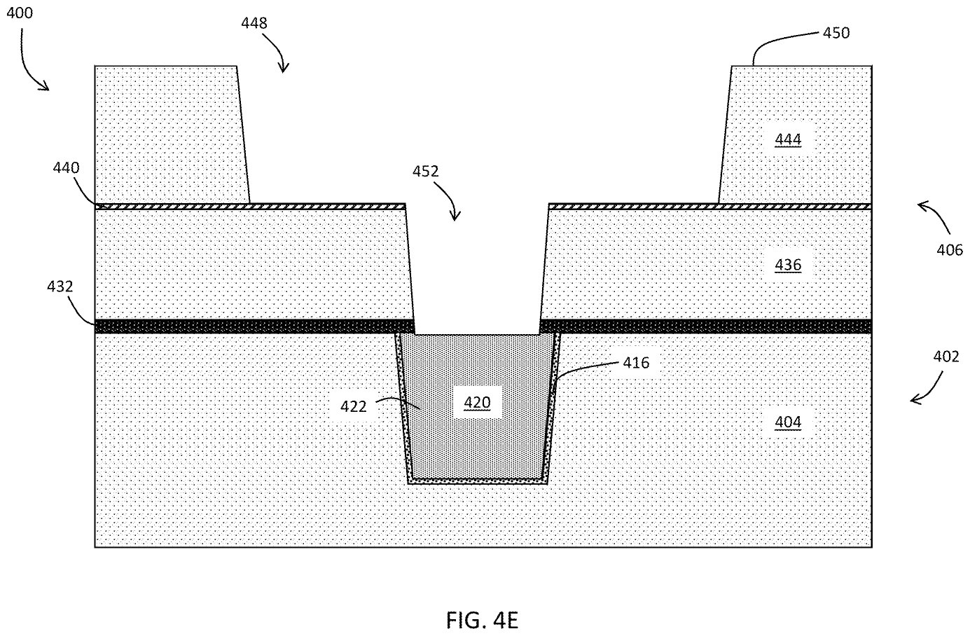

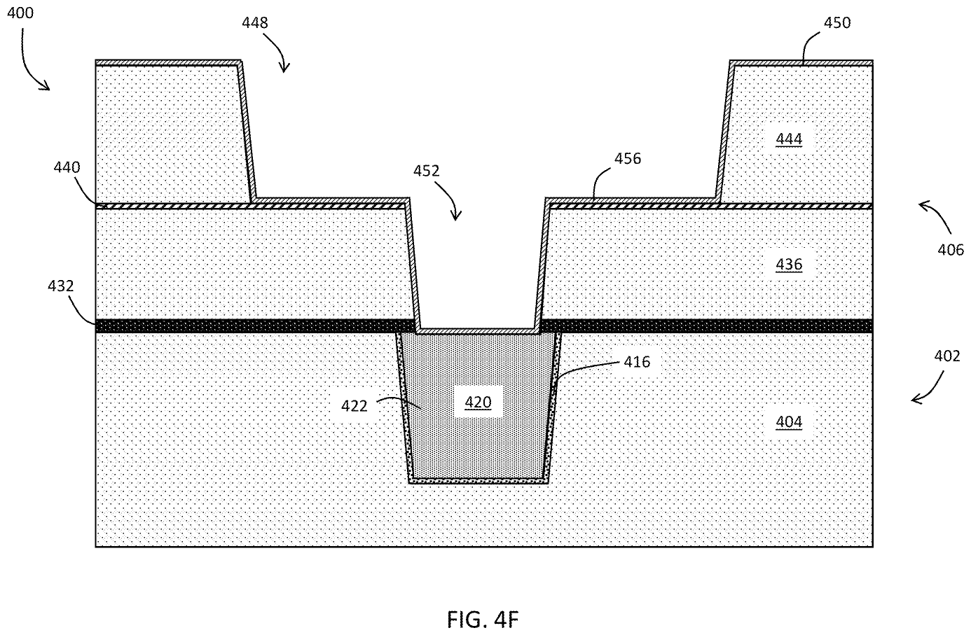

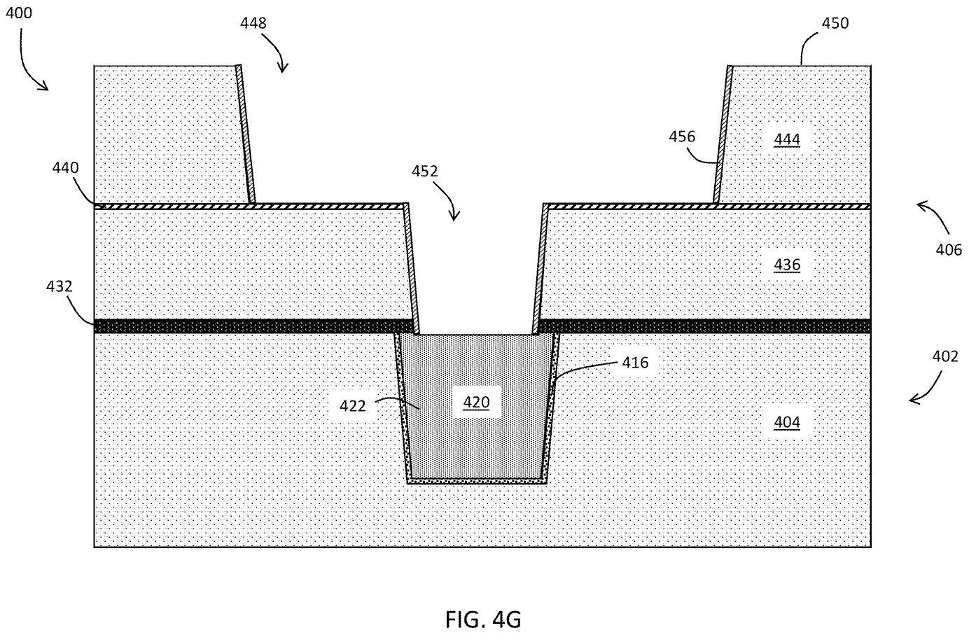

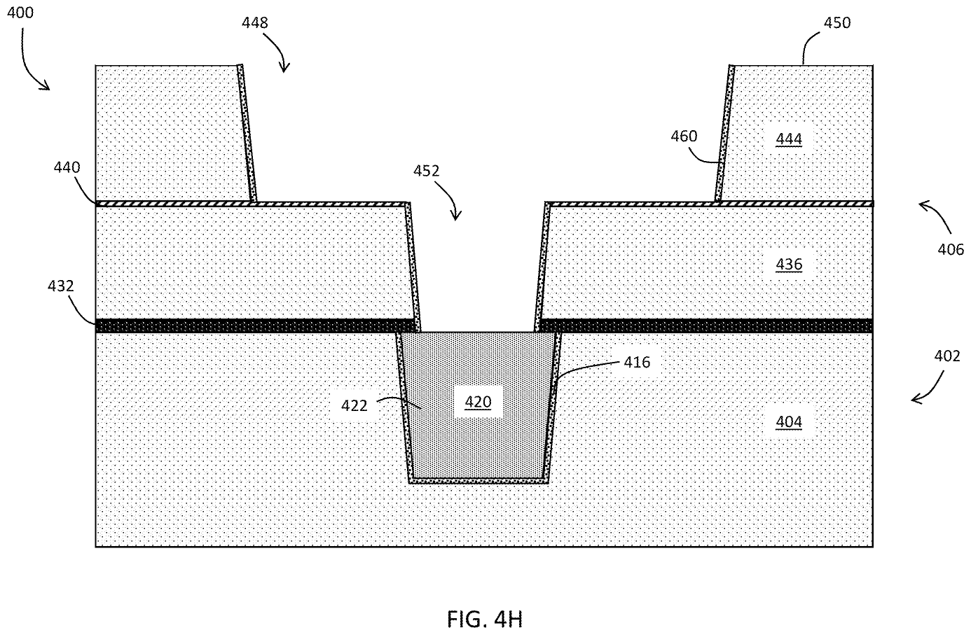

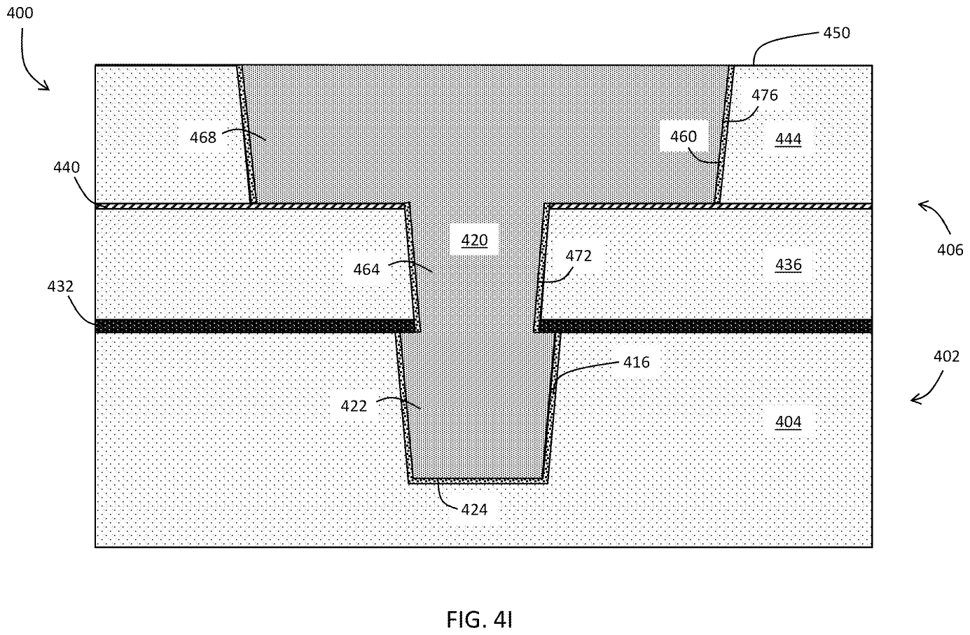

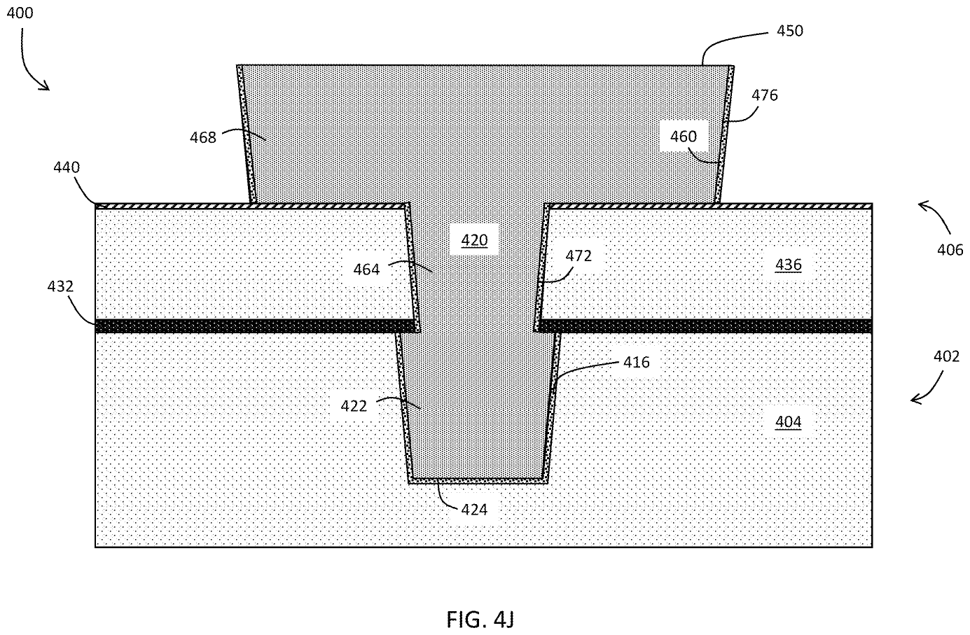

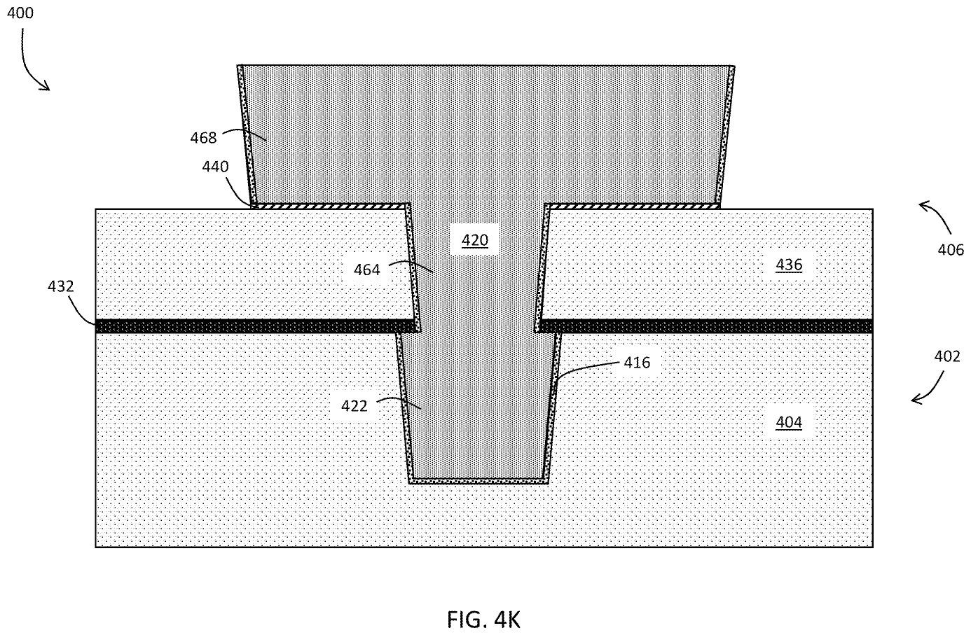

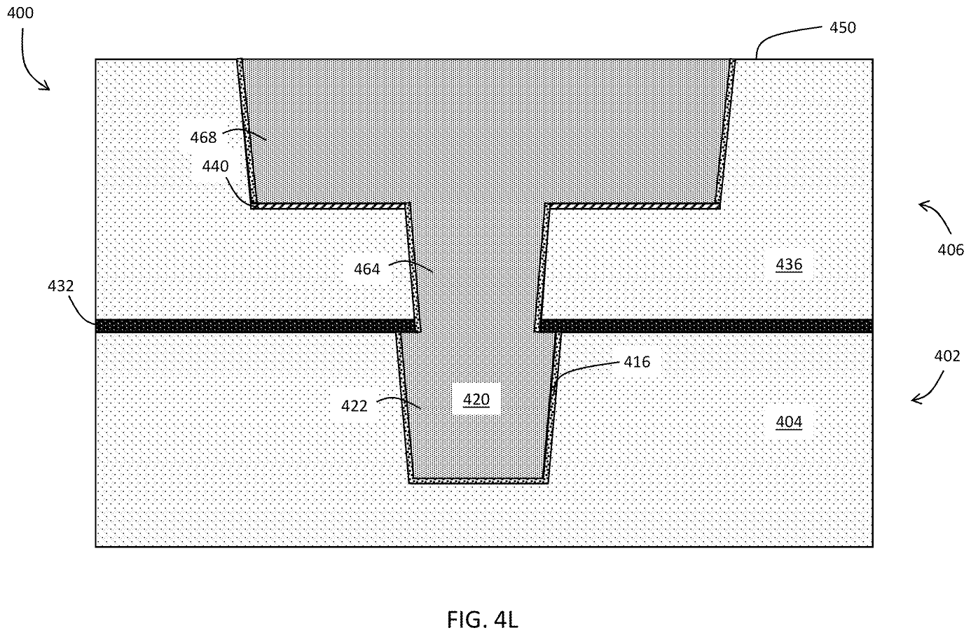

FIG. 4A depicts an example structure 400 following the performance of the above portions of operation 304. In particular, FIG. 4A depicts a lower level 402 of the structure 400. More specifically, the lower level 402 includes a first dielectric layer 404, a lower level line trench 408 formed in the first dielectric layer 404, and a very thin barrier layer 412. As shown, the very thin barrier layer 412 covers the first dielectric layer 404, including the surfaces of the lower level line trench 408.

In accordance with at least one embodiment of the present disclosure, the performance of operation 304 further includes converting the barrier material of the barrier layer into a further barrier material. In particular, for embodiments in which the barrier material is tantalum, the performance of operation 304 includes converting the tantalum into TaS2. In accordance with at least one embodiment of the present disclosure, converting tantalum into TaS2 is accomplished by reacting the tantalum with sulfur radicals.

FIG. 4B depicts the example structure 400 following the performance of this portion of operation 304. In particular, in FIG. 4B, the barrier layer 412 has been converted to a further barrier layer 416.

In accordance with at least one embodiment of the present disclosure, the performance of operation 304 further includes filling the lower level line trench with interconnect material. In accordance with at least one embodiment of the present disclosure, the interconnect material is copper. Further discussion refers to the interconnect material as copper, but other suitable interconnect materials may be used instead of copper. The copper of the resulting lower level line is in direct contact with the further barrier layer. In accordance with at least one embodiment of the present disclosure, the performance of operation 304 further includes planarizing the structure to remove excess interconnect material as well as to remove the further barrier material that is outside of the lower level line trench. In accordance with at least one embodiment of the present disclosure, planarizing the structure can include performing CMP on the structure.

FIG. 4C depicts the example structure 400 following the performance of operation 304. In particular, in FIG. 4C, the lower level line trench 408 has been filled with copper 420 to form a lower level line 422 of the interconnect structure. Accordingly, the copper 420 is separated from the surrounding dielectric material of the first dielectric layer 404 by the further barrier layer 416 of TaS2. The copper 420 is also in direct contact with the further barrier layer 416. More specifically, by lining the lower level line trench 408, the further barrier layer 416 forms a bottom wall 424 and a side wall 428 that partially delimit the copper 420 of the lower level line 422. As shown, any excess copper has been removed from outside of the lower level line trench 408, and any further barrier layer 416 outside of the lower level line trench 408 has also been removed. Additionally, the top surface of the structure is made planar by the CMP procedure.

Returning to FIG. 3, the method 300 proceeds from operation 304 to operation 308, wherein an upper level of the interconnect structure is formed. In accordance with at least one embodiment of the present disclosure, the performance of operation 308 further includes the performance of a number of sub-operations.

In accordance with at least one embodiment of the present disclosure, the performance of operation 308 includes depositing a capping layer on top of the first dielectric layer and the further barrier layer and lower level line formed in the trench. In accordance with at least one embodiment of the present disclosure, the capping layer can be made of, for example, SiCN.

In accordance with at least one embodiment of the present disclosure, the performance of operation 308 further includes depositing a second dielectric layer on top of the capping layer. In accordance with at least one embodiment of the present disclosure, the second dielectric layer is made of a low-k dielectric material. In accordance with at least one embodiment of the present disclosure, the second dielectric layer is made of the same material as the first dielectric layer. In alternative embodiments, the second dielectric layer can be made of a different material than that of the first dielectric layer.

In accordance with at least one embodiment of the present disclosure, the performance of operation 308 further includes depositing an etch stop layer on top of the second dielectric layer. In such embodiments, the distance between the capping layer and the etch stop layer determines the height of the via that will be formed by subsequent processes. The etch stop layer will ultimately act as a diffusion barrier at the bottom of the upper level line. Accordingly, the etch stop layer is made of a material or materials that are suitable to act as such a diffusion barrier. In accordance with at least one embodiment of the present disclosure, the etch stop layer can be made of a material or layers of materials, such as, for example: Ta, TaN, Ta/TaN, Ta/Ru, Ta/Co, TaN/Co, Ta/TaN/Ru, or Ta/TaN/Co.

In accordance with at least one embodiment of the present disclosure, the performance of operation 308 further includes depositing a third dielectric layer on top of the etch stop layer. Accordingly, the etch stop layer is a barrier layer between the second dielectric layer and the third dielectric layer. In such embodiments, the thickness of the third dielectric layer determines the height of the upper level line that will be formed by subsequent processes. In accordance with at least one embodiment of the present disclosure, the third dielectric layer is made of a low-k dielectric material. In accordance with at least one embodiment of the present disclosure, the third dielectric layer is made of the same material as the second dielectric layer. In alternative embodiments, the third dielectric layer can be made of a material that is different than that of the second dielectric layer. In at least one embodiment, the first dielectric layer, the second dielectric layer, and the third dielectric layer can all be made of the same material. In at least one embodiment, the first dielectric layer, the second dielectric layer, and the third dielectric layer can all be made of different materials.

FIG. 4D depicts the structure 400 following the performance of operation 308. As shown, an upper level 406 is formed on top of the lower level 402 of the structure 400. More specifically, the upper level 406 includes a capping layer 432, a second dielectric layer 436, an etch stop layer 440, and a third dielectric layer 444.

The capping layer 432 is arranged on top of the first dielectric layer 404, the further barrier layer 416, and the copper 420 of the lower level line 422. Additionally, the second dielectric layer 436 is arranged on top of the capping layer 432. Additionally, the etch stop layer 440 is arranged on top of the second dielectric layer 436, and a third dielectric layer 444 is arranged on top of the etch stop layer 440. As noted above, following the performance of further processes, an upper level line will be formed such that the etch stop layer 440 will act as a diffusion barrier at the bottom of the upper level line to separate the copper of the upper level line from the second dielectric layer 436.

Returning to FIG. 3, the method 300 proceeds from operation 308 to operation 312, wherein an upper level barrier is formed. In accordance with at least one embodiment of the present disclosure, operation 312 further includes a number of sub-operations.

In accordance with at least one embodiment of the present disclosure, the performance of operation 312 includes forming a cavity including an upper level line trench and an upper level via trench. The upper level line trench extends through the third dielectric layer. Accordingly, the upper level line trench extends from the uppermost surface of the upper level of the structure to the etch stop layer. The depth of the upper level line trench stops at the etch stop layer. More specifically, in accordance with at least one embodiment, the upper level line trench is formed by patterning and etching, and the etching stops at the etch stop layer. In other words, the formation of the upper level line exposes a portion of the etch stop layer. Advantageously, for embodiments wherein multiple upper level line trenches are being formed simultaneously in the performance of the method 300, the selectivity of the etch to the etch stop layer allows all trenches to be formed with the same depth, even if they have different width dimensions.

The upper level via trench extends from the bottom of the upper level line trench downwardly through the etch stop layer, through the second dielectric layer, and through the capping layer. Accordingly, the upper level via trench is continuous with the upper level line trench and extends down to the copper that forms the lower level line. The depth of the upper level via trench stops at the copper of the lower level line. More specifically, in accordance with at least one embodiment, the upper level via trench is formed by patterning and etching, and the etching stops at the copper of the lower level line. In other words, the formation of the upper level via trench exposes a portion of the lower level line. In accordance with at least one embodiment, the upper level line trench and the upper level via trench are formed by performing a dual damascene process.

FIG. 4E depicts the structure 400 following the performance of these portions of operation 312. As shown, the upper level 406 of the structure 400 includes an upper level line trench 448 that extends from the uppermost surface 450 of the structure 400 to the etch stop layer 440. Additionally, the upper level 406 of the structure 400 includes an upper level via trench 452 that is continuous with the upper level line trench 448 and extends down to the copper 420 that forms the lower level line 422 in the lower level 402 of the structure. Accordingly, the upper level via trench 452 is delimited by the copper 420 that forms the lower level line 422, by the capping layer 432, by the second dielectric layer 436, and by the etch stop layer 440. The upper level line trench 448 is delimited by the etch stop layer 440 and by the third dielectric layer 444. In other words, the formation of the upper level line trench 448 exposes a portion of the etch stop layer 440 and a portion of the third dielectric layer 444. Similarly, the formation of the upper level via trench 452 exposes a portion of the copper 420 that forms the lower level line 422, a portion of the capping layer 432, a portion of the second dielectric layer 436, and a portion of the etch stop layer 440.

In accordance with at least one embodiment of the present disclosure, the performance of operation 312 further includes forming a thin upper level barrier layer on the surfaces of the structure exposed by the formation of the upper level line trench and upper level via trench. In accordance with at least one embodiment, the thin upper level barrier layer can be formed by deposition. In accordance with at least one embodiment, the thin upper level barrier layer can be made of, for example, tantalum. In accordance with at least one embodiment, the thin upper level barrier layer is substantially similar to the very thin barrier layer that was deposited on the first dielectric layer during the performance of operation 304. In accordance with at least one embodiment, the thin upper level barrier layer is the same as the very thin barrier layer that was deposited on the first dielectric layer during the performance of operation 304. In accordance with at least some embodiments, the thin upper level barrier layer may have a thickness of, for example, approximately 1-3 nanometers.

FIG. 4F depicts the structure 400 following the performance of these portions of operation 312. As shown, a thin upper level barrier layer 456 has been deposited over the structure 400. Accordingly, surfaces of the copper 420 of the lower level line 422, the capping layer 432, the second dielectric layer 436, the etch stop layer 440, and the third dielectric layer 444 that were exposed by the formation of the upper level line trench 448 and the upper level via trench 452, as well as the uppermost surface 450 of the structure 400, are covered by the thin upper level barrier layer 456.

In accordance with at least one embodiment of the present disclosure, the performance of operation 312 further includes removing the thin upper level barrier layer from the substantially horizontal surfaces of the structure. In particular, the thin upper level barrier layer is removed from the substantially horizontal surface on top of the copper that forms the lower level line. The thin upper level barrier layer is removed from the substantially horizontal surface on top of the etch stop layer at the bottom of the upper level line trench. The thin upper level barrier layer is also removed from the substantially horizontal surface on top of the third dielectric layer that forms the top of the structure. Accordingly, the thin upper level barrier layer remains only on surfaces that are not substantially horizontal. In particular, the thin upper level barrier layer remains on non-substantially horizontal surfaces of the capping layer, the second dielectric layer, the etch stop layer, and the third dielectric layer.

In accordance with at least one embodiment of the present disclosure, the thin upper level barrier layer is removed from the substantially horizontal surfaces of the structure by performing an etch back process. Such embodiments remove only a small amount of the thin upper level barrier layer from the non-substantially horizontal surfaces, which allows the upper level barrier layer to remain on such surfaces.

Following the performance of this portion of operation 312, the substantially horizontal surface on top of the copper of the lower level line is exposed by the upper level via trench. In other words, there is no structure or substance above the portion of the copper of the lower level line that is exposed by the upper level via trench. Similarly, the substantially horizontal surface on top of the etch stop layer is exposed by the upper level line trench. In other words, there is no structure or substance above the portion of the etch stop layer that is exposed by the upper level line trench.

FIG. 4G depicts the structure 400 following the performance of these portions of operation 312. As shown, the upper level barrier layer 456 has been etched back such that the upper level barrier layer 456 remains on non-substantially horizontal surfaces of the capping layer 432, the second dielectric layer 436, the etch stop layer 440, and the third dielectric layer 444 and has been removed from substantially horizontal surfaces of the copper 420 of the lower level line 422, the etch stop layer 440, and the third dielectric layer 444.

In accordance with at least one embodiment of the present disclosure, the performance of operation 312 further includes converting the barrier material of the upper level barrier layer into a further barrier material. In particular, for embodiments in which the barrier material of the upper level barrier layer is tantalum, the performance of operation 312 includes converting the tantalum into TaS2. In accordance with at least one embodiment of the present disclosure, converting tantalum into TaS2 is accomplished by reacting the tantalum with sulfur radicals.

FIG. 4H depicts the example structure 400 following the performance of this portion of operation 312. In particular, in FIG. 4H, the upper level barrier layer 456 has been converted to a further upper level barrier layer 460.

Following the performance of this portion of operation 312, the upper level barrier is formed. In other words, FIG. 4H depicts the example structure 400 following the performance of operation 312. As shown, the portion of the further upper level barrier layer 460 that covers the non-substantially horizontal surface of the third dielectric layer 444 abuts the exposed portions of the etch stop layer 440. In other words, the further upper level barrier layer 460 is in direct contact with the etch stop layer 440 such that the third dielectric layer 444 is isolated from the upper level line trench 448. Similarly, the portion of the further upper level barrier layer 460 that covers the non-substantially horizontal surface of the second dielectric layer 436 abuts the exposed portions of the etch stop layer 440 and the exposed portions of the copper 420. In other words, the further upper level barrier layer 460 is also in direct contact with the copper 420 and the etch stop layer 440 such that the second dielectric layer 436 is isolated from the upper level via trench 452.

Thus, the further upper level barrier layer 460 has been removed from the bottom of the upper level via trench 452 while the presence of the etch stop layer 440 remains at the bottom of the upper level line trench 448.

Returning to FIG. 3, the method 300 proceeds from operation 312 to 316, wherein the structure is finalized. In accordance with at least one embodiment of the present disclosure, the performance of operation 316 further includes the performance of a number of sub-operations.

In accordance with at least one embodiment of the present disclosure, the performance of operation 316 includes filling the upper level via trench and the upper level line trench with interconnect material. In accordance with at least one embodiment, the interconnect material is copper. Further discussion refers to the interconnect material as copper, but other suitable interconnect materials may be used instead of copper. Because the top surface of the copper of the lower level line has been exposed by the removal of the upper level barrier layer from the bottom of the upper level via trench, the copper that fills the upper level via trench is in direct contact with the copper that forms the lower level line. Accordingly, there is no structure or substance between the copper that forms the resulting upper level via and the copper that forms lower level line. In other words, the upper level via and the lower level line are continuous and are integrally formed with one another. In accordance with at least one embodiment, the performance of operation 316 further includes performing a CMP process after filling.

FIG. 4I depicts the example structure 400 following the performance of these portions of operation 316. As shown, the upper level line trench 448 (shown in FIG. 4H) and the upper level via trench 452 (shown in FIG. 4H) have been filled with copper such that the copper 420 that forms the lower level line 422 is continuous with the copper that forms the upper level via 464 and the upper level line 468. In other words, the copper 420 extends, uninterrupted, from the bottom wall 424 of the further barrier layer 416 at the bottom of the lower level line 422 to the uppermost surface 450 of the structure 400. Thus, the copper 420 forms a single, continuous interconnect structure that includes the lower level line 422, the upper level via 464, and the upper level line 468.

The copper 420 of the lower level line 422 is separated from the first dielectric layer 404 by the bottom wall 424 of the further barrier layer 416 and by the side wall 428 of the further barrier layer 416. Additionally, the copper 420 of the lower level line 422 is in direct contact with the bottom wall 424 and the side wall 428. In other words, the lower level line 422 is partially delimited by the bottom wall 424 and is partially delimited by the side wall 428. As shown in FIG. 4I, the lower level line 422 is also partially delimited by the capping layer 432.

The copper 420 of the upper level via 464 is separated from the second dielectric layer 436 by a side wall 472 of the further upper barrier layer 460. Additionally, the copper 420 of the upper level via 464 is in direct contact with the side wall 472. In other words, the upper level via 464 is partially delimited by the side wall 472.

The copper 420 of the upper level line 468 is separated from the third dielectric layer 444 by a side wall 476 of the further upper barrier layer 460 and is separated from the second dielectric layer 436 by the etch stop layer 440. In other words, the etch stop layer 440 forms a bottom wall of the upper level line 468. The copper 420 of the upper level line 468 is also in direct contact with the side wall 476 and with the etch stop layer 440. In other words, the upper level line 468 is partially delimited by the side wall 476 and is partially delimited by the etch stop layer 440.

As explained above, the copper 420 forms one continuous interconnect structure that is included in both the lower level 402 and the upper level 406 of the structure 400. Accordingly, there is no interface between the upper level via 464 and the lower level line 422. Thus, the structure 400 includes a thin layer of liner/barrier material for each of the side and bottom surfaces of the continuous copper interconnect structure 420, thereby preventing diffusion of the copper 420 into the surrounding dielectric layers 404, 436, 444, and the structure 400 does not include a liner/barrier material at an interface between the copper 420 that forms the upper level via 464 and the copper 420 that forms the lower level line 422, thereby preventing high resistivity at the bottom of the upper level via 464.

In accordance with at least one embodiment of the present disclosure, the performance of operation 316 further includes removing the etch stop layer outside of the upper level line trench to prevent shorting with adjacently formed interconnect structures. In accordance with at least one embodiment of the present disclosure, the removal of the etch stop layer can be accomplished by removing the third dielectric layer, for example, by performing a wet or dry etch procedure, to expose the etch stop layer.

FIG. 4J depicts the structure 400 following the removal of the third dielectric layer 444 (shown in FIG. 4I) outside of the upper level line 468 to expose the etch stop layer 440.

In accordance with at least one embodiment of the present disclosure, the removal of the etch stop layer can be accomplished by further removing the exposed etch stop layer outside of the upper level line, for example, by performing a further wet or dry etch procedure.

FIG. 4K depicts the structure 400 following the removal of the etch stop layer 440 outside of the upper level line 468 to expose the second dielectric layer 436. As shown, the etch stop layer 440 remains intact at the bottom of the upper level line 468 and continues to provide a liner/barrier between the bottom of the upper level line 468 and the second dielectric layer 436.

In accordance with at least one embodiment of the present disclosure, the removal of the etch stop layer can be accomplished by further performing a fill procedure followed by a CMP procedure. The fill procedure includes filling the structure with dielectric material on top of the second dielectric layer until the dielectric material is substantially level with the uppermost surface of the structure at the top of the upper level line.

FIG. 4L depicts the structure 400 following filling and CMP. Accordingly, FIG. 4L depicts the structure 400 following the performance of operation 316. Therefore, FIG. 4L also depicts the structure 400 following the performance of the method 300. As shown, the structure 400 has been filled with fresh dielectric material on top of the second dielectric layer 436 such that the fresh dielectric material is substantially level with the uppermost surface 450 of the structure 400.

In addition to embodiments described above, other embodiments having fewer operational steps, more operational steps, or different operational steps are contemplated. Also, some embodiments may perform some or all of the above operational steps in a different order. Furthermore, multiple operations may occur at the same time or as an internal part of a larger process.

In the foregoing, reference is made to various embodiments. It should be understood, however, that this disclosure is not limited to the specifically described embodiments. Instead, any combination of the described features and elements, whether related to different embodiments or not, is contemplated to implement and practice this disclosure. Many modifications and variations may be apparent to those of ordinary skill in the art without departing from the scope and spirit of the described embodiments. Furthermore, although embodiments of this disclosure may achieve advantages over other possible solutions or over the prior art, whether or not a particular advantage is achieved by a given embodiment is not limiting of this disclosure. Thus, the described aspects, features, embodiments, and advantages are merely illustrative and are not considered elements or limitations of the appended claims except where explicitly recited in a claim(s).

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The terminology used herein is for the purpose of describing particular embodiments only and is not intended to be limiting of the various embodiments. As used herein, the singular forms “a,” “an,” and “the” are intended to include the plural forms as well, unless the context clearly indicates otherwise. It will be further understood that the terms “includes” and/or “including,” when used in this specification, specify the presence of the stated features, integers, steps, operations, elements, and/or components, but do not preclude the presence or addition of one or more other features, integers, steps, operations, elements, components, and/or groups thereof. In the previous detailed description of example embodiments of the various embodiments, reference was made to the accompanying drawings (where like numbers represent like elements), which form a part hereof, and in which is shown by way of illustration specific example embodiments in which the various embodiments may be practiced. These embodiments were described in sufficient detail to enable those skilled in the art to practice the embodiments, but other embodiments may be used, and logical, mechanical, electrical, and other changes may be made without departing from the scope of the various embodiments. In the previous description, numerous specific details were set forth to provide a thorough understanding the various embodiments. But, the various embodiments may be practiced without these specific details. In other instances, well-known circuits, structures, and techniques have not been shown in detail in order not to obscure embodiments.

As used herein, “a number of” when used with reference to items, means one or more items. For example, “a number of different types of networks” is one or more different types of networks.

When different reference numbers comprise a common number followed by differing letters (e.g., 100a, 100b, 100c) or punctuation followed by differing numbers (e.g., 100-1, 100-2, or 100.1, 100.2), use of the reference character only without the letter or following numbers (e.g., 100) may refer to the group of elements as a whole, any subset of the group, or an example specimen of the group.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

Different instances of the word “embodiment” as used within this specification do not necessarily refer to the same embodiment, but they may. Any data and data structures illustrated or described herein are examples only, and in other embodiments, different amounts of data, types of data, fields, numbers and types of fields, field names, numbers and types of rows, records, entries, or organizations of data may be used. In addition, any data may be combined with logic, so that a separate data structure may not be necessary. The previous detailed description is, therefore, not to be taken in a limiting sense.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Although the present invention has been described in terms of specific embodiments, it is anticipated that alterations and modification thereof will become apparent to the skilled in the art. Therefore, it is intended that the following claims be interpreted as covering all such alterations and modifications as fall within the true spirit and scope of the invention.

What is claimed is:

1. A method of making a semiconductor component, the method comprising:
forming a lower level including an interconnect structure;
forming an upper level including a first dielectric layer, a second dielectric layer, and a barrier layer arranged between the first and second dielectric layers;
forming a cavity in the upper level such that a portion of the interconnect structure and a portion of the barrier layer are exposed;
forming a barrier material on all surfaces exposed by the formation of the cavity;
removing the barrier material from all substantially horizontal surfaces exposed by the formation of the cavity; and
filling the cavity with an interconnect material such that the interconnect material is in direct contact with the interconnect structure and the barrier layer.

2. The method of claim 1, further comprising:
converting remaining barrier material into a further barrier material prior to filling the cavity.

3. The method of claim 2, wherein the barrier material is tantalum and the further barrier material is tantalum disulfide.

4. The method of claim 1, wherein:
forming the cavity includes forming a via trench and a line trench,
the via trench exposes the portion of the interconnect structure, and
the line trench exposes the portion of the barrier layer.

5. The method of claim 1, further comprising:
removing the barrier layer that is arranged outside of the cavity after filling the cavity.

6. The method of claim 1, wherein the barrier layer is made of a different material than the barrier material.

7. The method of claim 1, wherein removing the applied barrier material does not include removing the exposed portion of the barrier layer.

8. A semiconductor component, comprising:
a lower level line separated from surrounding dielectric material by a sidewall made of a first liner material;
a via arranged in direct contact with the lower level line and separated from surrounding dielectric material by a sidewall made of a second liner material; and
an upper level line arranged in direct contact with the via and separated from surrounding dielectric material by a sidewall made of the second liner material and by a bottom wall made of a third liner material.

9. The semiconductor component of claim 8, wherein:
the second liner material is different than the third liner material.

10. The semiconductor component of claim 8, wherein:
the first liner material is the same as the second liner material.

11. The semiconductor component of claim 8, wherein:
the dielectric material surrounding the lower level line is separated from the dielectric material surrounding the via by a capping layer.

12. The semiconductor component of claim 8, wherein:
the via is integrally formed with the lower level line.

13. The semiconductor component of claim 8, wherein:
the bottom wall is substantially horizontal, and
the sidewalls are not substantially horizontal.

14. The semiconductor component of claim 8, wherein:
the bottom wall is in direct contact with the sidewall that separates the via from the surrounding dielectric material, and
the bottom wall is in direct contact with the sidewall that separates the upper level line from the surrounding dielectric material.

15. The semiconductor component of claim 8, wherein:
the lower level line is made of an interconnect material,
the via is made of the interconnect material, and
the interconnect material of the lower level line and of the via are continuous with one another.

16. A semiconductor component, comprising:
a continuous interconnect structure made of a single piece of interconnect material extending from a bottom surface of the interconnect structure to a top surface of the interconnect structure, the interconnect structure including:
a lower level line;
an upper level line; and
a via extending from the lower level line to the upper level line.

17. The semiconductor component of claim 16, wherein the lower level line is partially delimited by the bottom surface of the interconnect structure.

18. The semiconductor component of claim 16, wherein the upper level line is partially delimited by the top surface of the interconnect structure.

19. The semiconductor component of claim 18, wherein the upper level line is partially delimited by a bottom wall made of a first barrier material.

20. The semiconductor component of claim 19, wherein:
the via is partially delimited by a side wall made of a second barrier material; and
the second barrier material is different than the first barrier material.
